(19) United States
(12) Patent Application Publication
(10) Pub. No.: US 2008/0160749 A1
(43) Pub. Date: Jul. 3, 2008

(54) Semiconductor device and method of forming thereof

(75) Inventor: David A. Rothenbury, Garland, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/645,867

(22) Filed: Dec. 27, 2006

(51) Int. Cl. H01L 21/44

(52) U.S. Cl. 438/597

(57) ABSTRACT

A semiconductor device and method of forming thereof. An embodiment comprises forming a spacer layer on a substrate, forming a via having walls and a bottom in the spacer layer, depositing a conformal first conductive layer on the spacer layer and on the walls and the bottom of the via, forming a nucleating layer over the conformal first conductive layer, forming a conformal second conductive layer over the nucleating layer, and removing the spacer layer. The nucleating layer helps in the formation of the conformal second conductive layer, thereby creating a more uniform coating of the conformal first conductive layer with better step coverage.

### TECHNICAL FIELD

The present invention relates generally to integrated circuits, and more particularly to a semiconductor device and method of forming thereof.

### BACKGROUND

A via, generally a plated hole etched in one or more layers of an integrated circuit and used to provide a vertical connection between different layers, may be used for many different purposes. A via may provide electrical connectivity between different layers of the integrated circuit. Additionally, in certain integrated circuits, such as a micro-electro-mechanical system (MEMS), a via may provide mechanical connectivity between structures in the integrated circuit. A via may therefore be used to provide both electrical and mechanical connectivity.

In a digital micromirror device (DMD) based projection display system, wherein a large number of micromirrors pivot along an axis based on image data from an image being displayed, vias may be used to provide electrical connectivity between distant conductive layers and conductors. Additionally, other vias may be used to create a support member for each micromirror, physically attaching the micromirror to a hinge and its support.

Covering the walls of a via with a desired material may be critical in creating a good electrical and/or mechanical contact between the different layers. A measure of the ability of a manufacturing process' ability to cover the walls of a via is commonly referred to as the process' step coverage. Generally the better the step coverage, the better the covering of the via's walls, and the better the electrical and/or mechanical contact.

### SUMMARY OF THE INVENTION

These and other problems are generally solved or circumvented, and technical advantages are generally achieved, by embodiments of the present invention which provide a semiconductor device and a method of forming thereof.

In accordance with an embodiment, a method for forming a semiconductor device is provided. The method includes forming a spacer layer on a substrate, forming a via having walls and a bottom in the spacer layer, and depositing a conformal first conductive layer on the spacer layer and on the walls and the bottom of the via. The method also includes forming a nucleating layer over the conformal first conductive layer, forming a conformal second conductive layer over the nucleating layer, and removing the spacer layer.

In accordance with another embodiment, a semiconductor device is provided. The semiconductor device includes a first conductive layer disposed over a substrate, a set of first conductive supports disposed on the first conductive layer, a second conductive layer disposed over the first supports above the first layer, a nucleating layer disposed over the second layer, and a third conductive layer disposed over the nucleating layer. Each of the first supports comprises a circumferential pillar of conductive material, and portions of the second conductive layer not overlying the first supports are separated from the first conductive layer by a vacuum or a gas.

In accordance with another embodiment, a method for fabricating a semiconductor device is provided. The method includes forming a first conductive layer on a substrate, depositing a first spacer layer on the first conductive layer, and creating a first opening in the first spacer layer to expose at least a portion of the first conductive layer. The method also includes forming a second conductive layer over the first spacer layer, conformally coating an interior of the first opening, forming a nucleating layer on the second conductive layer, forming a third conductive layer over the nucleating layer, and removing the first spacer layer.

An advantage of an embodiment is that the improvements in step coverage are achievable without requiring any new manufacturing equipment and/or processes. This may significantly reduce the manufacturing costs involved in manufacturing the integrated circuit, which may be passed on to customers.

A further advantage of an embodiment is that existing techniques for improving step coverage may also be implemented. Therefore, step coverage improvement achievable using the existing techniques may further be improved.

Yet another advantage of an embodiment is that even when new manufacturing equipment and/or processes are used, integration is very simple and does not require significant modifications to existing manufacturing equipment and/or processes. This may help to keep manufacturing costs at a minimum.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the embodiments, and the advantages thereof, reference is now made to the following descriptions taken in conjunction with the accompanying drawings, in which:

FIGS. 1a through 1c are diagrams of cross-sectional views of portions of integrated circuits, showing prior art techniques for improving step coverage of the interior of vias;

FIGS. 2a through 2e are diagrams of cross-sectional views of portions of integrated circuits, showing an integrated circuit as it undergoes various manufacturing process steps;

FIG. 3 is a diagram of a cross-sectional view of a DMD;

FIG. 4 is a diagram of an exemplary display system; and

FIG. 5 is a diagram of a sequence of events in the fabrication of a multilayer film used to improve step coverage of an interior of a via.

### DETAILED DESCRIPTION OF ILLUSTRATIVE EMBODIMENTS

The making and using of the embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The embodiments will be described in a specific context, namely a MEMS commonly referred to as a digital micromirror device (DMD), used as a microdisplay in a projection display system. The invention may also be applied, however, to other MEMS and integrated circuits wherein there is a desire to improve step coverage in vias.

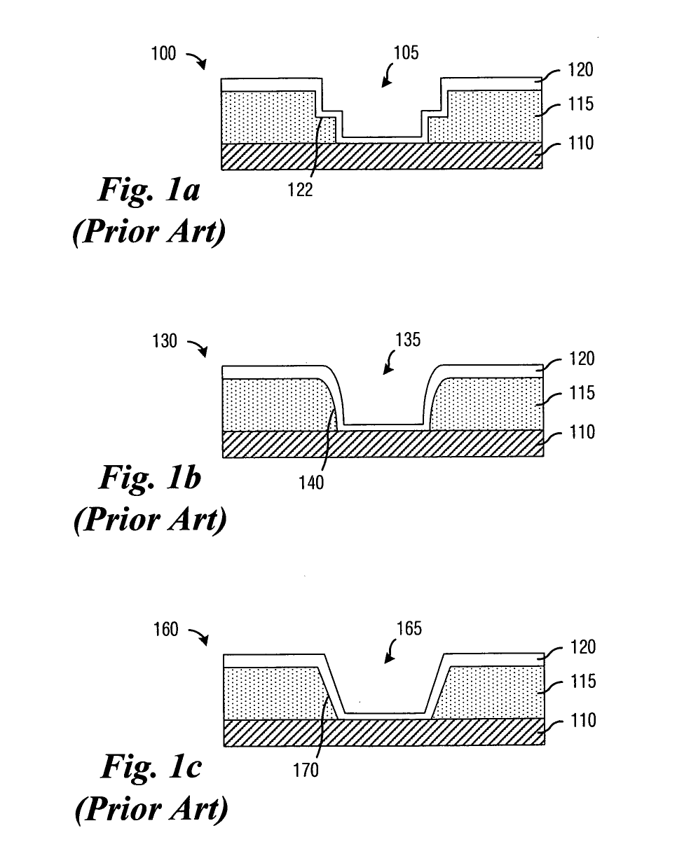

With reference now to FIGS. 1a through 1c, there are shown diagrams illustrating cross-sectional views of portions of integrated circuits. The diagrams illustrate prior art techniques for step coverage of via walls. The diagram shown in FIG. 1 a illustrates an integrated circuit 100 with a via 105 created with a first technique for step coverage. The integrated circuit 100 includes a first layer 110, a second layer 115, and a third layer 120. The via 105 may be created in the second layer 115 to permit electrical and/or mechanical connectivity between the first layer 1 10 and the third layer 120. Rather than having straight walls (vertical walls), such as in a typical via, the via 105 may have stepped walls, such as step 122. The presence of the steps in the walls of the via 105 effectively shorten the walls of the via 105, thereby reducing a vertical drop that must be covered by the material used to cover the walls, typically the same material as used in the third layer 120. Furthermore, the horizontal portion of the step 122 may increase the step coverage by improving the adhesion of the material used to cover the walls. An example of a stepped walled via is described in U.S. Pat. No. 4,999,318, entitled “Method for Forming Metal Layer Interconnects Using Stepped Via Walls,” issued Mar. 12, 1991, which is incorporated herein by reference.

The diagram shown in FIG. 1b illustrates an integrated circuit 130 with a via 135 created with a second technique for step coverage. The integrated circuit 130 includes a first layer 110, a second layer 115, and a third layer 120. Rather than having straight walls or stepped walls (as shown in FIG. 1a), the via 135 may have rounded or radiused walls 140. The radius in the radiused walls 140 may provide a horizontal component to the walls of the via 135, thereby increasing the step coverage by improving the adhesion of the material used to cover the walls of the via 135. An example of a radiused walled via is described in U.S. Pat. No. 4,645,562, entitled “Double Layer Photoresist Technique for Side-Wall Profile Control in Plasma Etching Processes,” issued Feb. 24, 1987, which is incorporated herein by reference. Similarly, the diagram shown in FIG. 1c illustrates an integrated circuit 160 with a via 165 created with a third technique for step coverage. The via 165 may have sloped walls 170. Like the radiused walls 140, the sloped walls 170 may provide a horizontal component to the walls of the via 165, thereby increasing the step coverage by improving the adhesion of the material used to cover the walls of the via 165. An example of a radiused walled via is described in U.S. Pat. No. 4,931,144, entitled “Self-Aligned Nonnested Sloped Via,” issued Jun. 5, 1990, which is incorporated herein by reference.

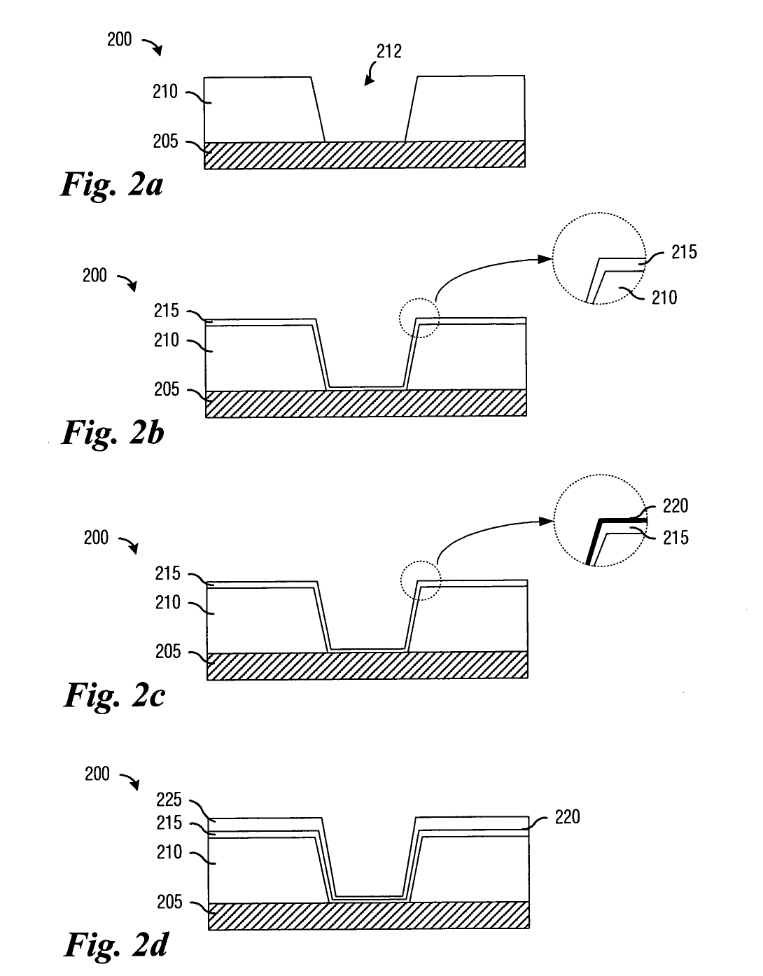

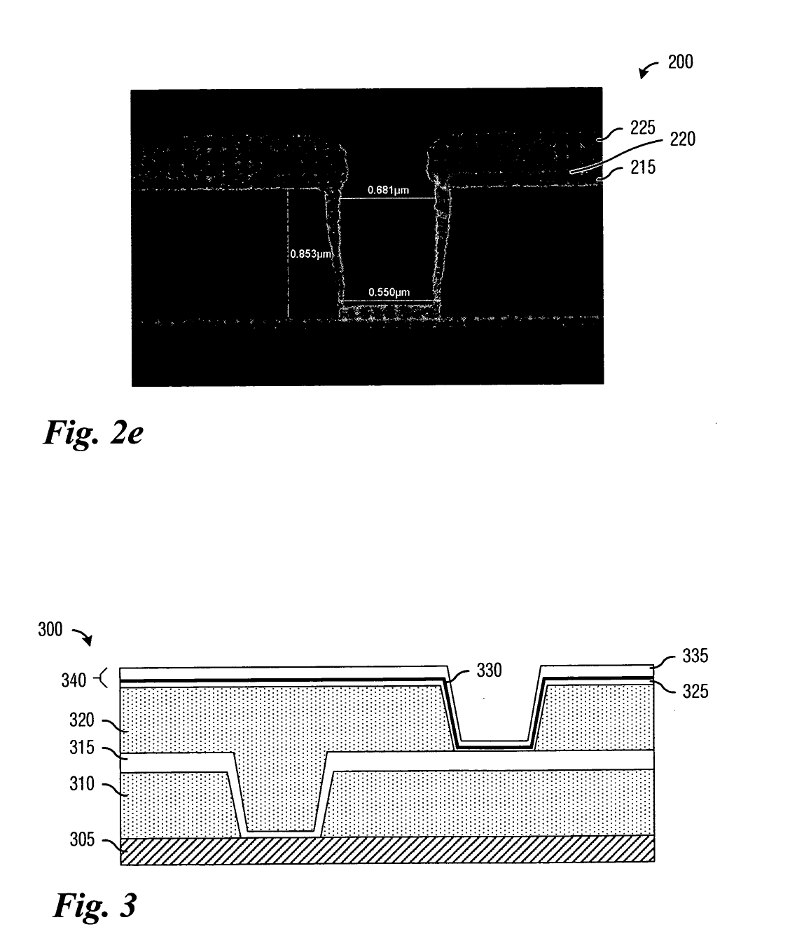

With reference now to FIGS. 2a through 2e, there are shown diagrams of cross-sectional views of a portion of an integrated circuit 200. The diagrams shown in FIGS. 2a through 2d illustrate the integrated circuit 200 as it undergoes various manufacturing process steps and the diagram shown in FIG. 2e is an electron-micrograph of a cross-section of the integrated circuit 200.

The diagram shown in FIG. 2a illustrates the integrated circuit 200 comprising a first layer 205 and a spacer layer 210. The spacer layer 210 may contain a via 212. The via 212 may have the rough appearance of a substantially round pillar. The first layer 205 may be a conductive layer, formed from a metallic material or polysilicon, while the spacer layer 210 may be created from a spin-on resist material that may have been patterned using standard photo-definable techniques to create the via 212. As shown in FIG. 2a, the via 212 may have sloped walls. However, in alternate embodiments, the via 212 may have stepped walls, radiused walls, straight walls, and so forth.

The diagram shown in FIG. 2b illustrates the integrated circuit 200 after a second layer 215 has been formed over the spacer layer 210. The second layer 215 may be formed using standard deposition techniques, such as directional and non-directional deposition techniques (including but not limited to evaporation, sputtering, chemical vapor deposition, and so forth). The deposition technique used should provide adequate step coverage to conformally coat the walls and bottom of the via 212 to afford the desired connectivity, electrical and/or mechanical. The second layer 215 may be formed from a metallic material, such as aluminum, alloys of aluminum, tungsten, alloys of tungsten, titanium, alloys of titanium, and so forth, or silicon, and so on.

The diagram shown in FIG. 2c illustrates the integrated circuit 200 after a nucleating layer 220 has been formed over the second layer 215. The nucleating layer 220 may serve as a nucleation surface to help in the adhesion of subsequently created layers, which may help to accelerate the formation of the subsequent layers as well as to facilitate a more even distribution of the material making up the subsequent layers. This may yield improved step coverage and better uniformity.

The nucleating layer 220 may be formed over the second layer 215 in several ways. A first technique for forming the nucleating layer 220 may be to simply expose the second layer 215 to oxygen. Depending on the material of the second layer 215, the duration of the exposure to oxygen or the environmental conditions may not be crucial. For example, if the second layer 215 is formed from aluminum, the oxide layer 220 may readily form when the integrated circuit 200 is exposed to oxygen under standard environmental conditions, which for a fabrication process, may be at a temperature of about 20 degrees Celsius and 50 percent relative humidity for approximately one hour. Under the above exposure conditions, a layer of aluminum oxide may form to a thickness ranging from about 30 to about 50 Angstroms. Extended exposure or exposure at different temperatures, relative humidity, or oxygen concentration yield substantially similar results. An overly thick nucleating layer 220 may result in better step coverage, but may also cause thermal stability issues due to different coefficients of thermal expansion. For materials other than aluminum, the exposure conditions may be different.

The integrated circuit 200, after the formation of the second layer 215, may be placed in an air brake and water wash for a specified amount of time to permit the formation of the nucleating layer 220 under standard environmental conditions. Alternatively, the integrated circuit 200 may be placed in an oxidation chamber to expose the second layer 215 of the integrated circuit 200 to elevated conditions, such as elevated temperatures and/or oxygen concentrations. In yet another alternate embodiment, an alternative to the nucleating layer 220 may be formed over the second layer 215. For example, a thin coating of silicon oxide, titanium oxide, tantalum oxide, other forms of oxides, may be formed over the second layer 215. Additionally, titanium nitride (TiN) and/or titanium aluminide (chemical formulae TiAl, Ti₃Al, TiAl₃, Ti-48Al-2Nb-2Cr, and Ti₂ AlNb) may be formed over the second layer 215. Generally, a wide range of materials may be used to form the nucleating layer 220. A desired characteristic of the material used should be that it forms a layer with a degree of roughness that may help in the nucleation of subsequent layers. If the material used results in the formation of a nucleation layer that is overly smooth, the formation of the subsequent layers may be retarded. In applications wherein the via 212 is expected to provide electrical connectivity, the oxide layer 220 or any of the alternate layers discussed above should also be electrically conductive.

The diagram shown in FIG. 2d illustrates the integrated circuit 200 after a third layer 225 has been formed over the nucleating layer 220. The third layer 225 may be formed from the same material as the second layer 215 and the combination of the second layer 215, the nucleating layer 220, and the third layer 225 provides a multilayer film intended to cover the via 212 and the spacer layer 210. For example, in a DMD, the multilayer film comprising the second layer 215, the nucleating layer 220, and the third layer 225 may be used to form a mirror with the portions of the multilayer film coating the via 212 forming an attachment for a mirror to an underlying hinge. The diagram shown in FIG. 2e illustrates an electron-micrograph of a cross-section of an integrated circuit 200. Shown are the second layer 215, the nucleating layer 220, and the third layer 225.

With reference now to FIG. 3, there is shown a diagram illustrating a cross-sectional view of a DMD 300. The DMD 300 includes two layers of vias. A first layer of vias is used to provide electrical connectivity between signal layers and a second layer of vias is used to create mechanical connectivity between micromirrors and hinges about which they pivot. The DMD 300 includes a substrate 305 that may contain electrical conductors, as well as memory cells. Formed on the substrate 305 may be a first spacer layer 310, which may be created from a photo-resist and then patterned and developed using any of a wide variety of standard photo-definable techniques. Then, formed on the first spacer layer 310 may be a conductive layer 315, which may be used to provide connectivity between various electrical address lines in the substrate 305 as well as to create hinges and hinge support structures. The hinges and hinge support structures may be used to support the micromirrors of the DMD as well as to permit the micromirrors to pivot based on image data loaded into their associated memory cells.

Formed above the conductive layer 315 may be a second spacer layer 320. As with the first spacer layer 310, the second spacer layer 320 may be formed from a photo-resist material and then patterned and developed using any of a wide variety of standard photo-definable techniques. Then, formed on the second spacer layer 320 may be a first mirror layer 325. Preferably, the first mirror layer may be formed from aluminum or an alloy of aluminum. However, other metallic materials, such as copper, tungsten, silver, and alloys thereof may be used.

After the formation of the first mirror layer 325 has been formed, a nucleating layer 330 may then be created on the first mirror layer 325. The nucleating layer 330 may be created by simply exposing the first mirror layer 325 to a standard fabrication environment without enhancement for a period of time. Alternatively, a specific process step utilizing fabrication equipment may be used to create the nucleating layer 330 on the first mirror layer 325. For example, oxides of materials other than the material used in the first mirror layer 325 may be formed over the first mirror layer 325. Also, a conductive ceramic, such as TiN, or titanium aluminide (chemical formulae TiAl, Ti₃Al, TiAl₃, Ti-48Al-2Nb-2Cr, and Ti₂ AlNb) may be formed over the first mirror layer 325. The nucleating layer 330 may function as an accelerant for the formation of a second mirror layer 335, formed above the nucleating layer 330. The surface of the nucleating layer 330 may serve as nucleation points for the formation of the second mirror layer 335. The first mirror layer 325, the nucleating layer 330, and the second mirror layer 335 may provide a multilayer film 340 forming the micromirrors of the DMD 300. After the formation of the second mirror layer 335, the fabrication of the DMD 300 may be completed with an isotropic etch to remove the first spacer layer 310 and the second spacer layer 320.

As discussed above, the conductive layer 315 formed above the first spacer layer 310 is formed in a single process step. However, it may be possible to replace the conductive layer 315 with a multilayer film, similar to the multilayer film 340 comprised of the first mirror layer 325, the nucleating layer 330, and the second mirror layer 335. Since the conductive layer 315 of the DMD 300 may be used to conduct electrical signals, the multilayer film used to replace the conductive layer 315 should be electrically conductive.

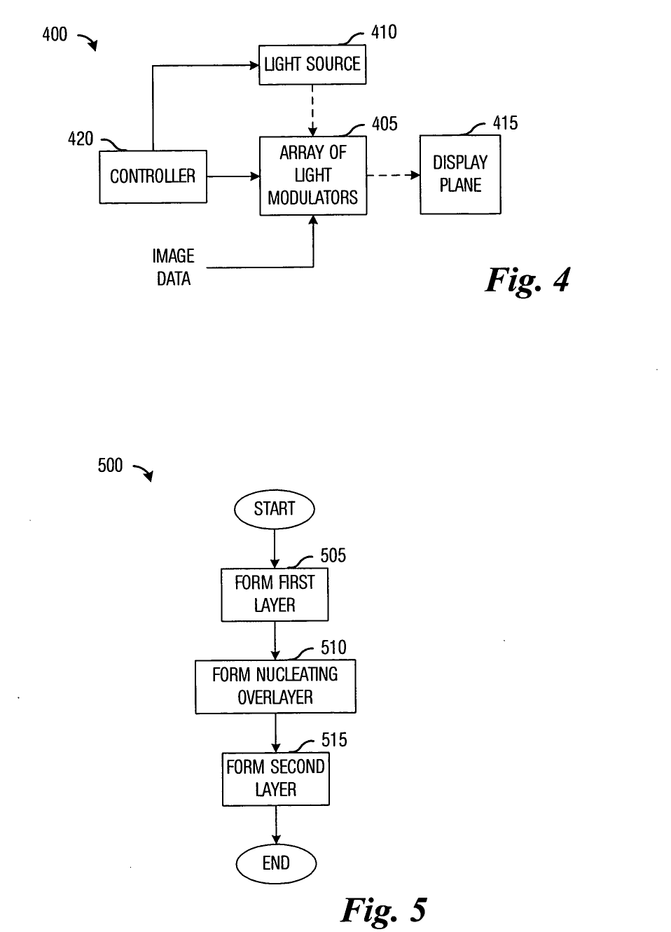

With reference now to FIG. 4, there is shown a diagram illustrating a display system 400, wherein the display system 400 makes use of a microdisplay containing multilayer films. The display system 400 utilizes a spatial light modulator, more specifically, an array of light modulators 405, wherein individual light modulators in the array of light modulators 405 assume a state corresponding to image data for an image being displayed by the display system 400. The array of light modulators 405 is preferably a digital micromirror device (DMD) with each light modulator being a positional micromirror. The positional micromirrors may be arranged in a rectangular array or a diamond array configuration. Light from a light source 410 may be reflected away from or towards a display plane 415, depending on image data corresponding to each micromirror. A combination of the reflected light from all of the light modulators in the array of light modulators 405 produces an image corresponding to the image data. A controller 420 coordinates the loading of the image data into the array of light modulators 405, controls the light source 410, and so forth.

With reference now to FIG. 5, there is shown a diagram illustrating a sequence of events 500 for use in fabricating a multilayer film used to cover via walls of an integrated circuit. The fabrication of the multilayer film may begin with the formation of a first layer over a spacer layer (block 505). The first layer may be formed from a metallic material, such as aluminum, copper, tungsten, silver, or alloys thereof. The first layer may also be formed from materials such as polysilicon. After the formation of the first layer, a nucleating layer may be formed over the first layer (block 510). Preferably, the nucleating layer may be formed by simply exposing the first layer to a standard fabrication environment for a period of time, about one hour at approximately 20 degrees Celsius with a relative humidity at about 50 percent, for example. The formation of the nucleating layer using the technique described above may result in an nucleating layer of about 30 to about 50 Angstroms in thickness. The nucleating layer may be formed during an air brake with water wash.

Alternatively, the nucleating layer may be formed in a specific fabrication process. For example, the integrated circuit may be placed in an oxidation chamber or a pressure oven to expose the integrated circuit to elevated temperatures and oxygen concentrations. Additionally, the nucleating layer may be replaced with a layer of TiN or titanium aluminide (chemical formulae TiAl, Ti₃Al, TiAl₃, Ti-48Al-2Nb-2Cr, and Ti₂ AlNb) deposited using standard vapor deposition techniques, such as physical vapor deposition or chemical vapor deposition.

After the formation of the nucleating layer, a second layer may be formed over the nucleating layer (block 515). Preferably, the second layer may be formed from the same material as used to form the first layer, for example, aluminum. The presence of the nucleating layer may function as an accelerant for the formation of a second layer, formed above the nucleating layer 330. The surface of the nucleating layer may serve as nucleation points for the formation of the second layer. After the formation of the second layer (block 515), the fabrication of the integrated circuit may continue to completion.

Although the embodiments and their advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method for forming a semiconductor device, the method comprising:
forming a spacer layer on a substrate;
forming a via having walls and a bottom in the spacer layer;
depositing a conformal first conductive layer on the spacer layer and on the walls and the bottom of the via;
forming a nucleating layer over the conformal first conductive layer;
forming a conformal second conductive layer over the nucleating layer; and
removing the spacer layer.

2. The method of claim 1, wherein the forming of the nucleating layer comprises exposing the conformal first conductive layer to an oxygen containing environment.

3. The method of claim 2, wherein the oxygen containing environment comprises an operating environment for a fabrication process used in creating the semiconductor device.

4. The method of claim 2, wherein the conformal first conductive layer is exposed to the oxygen containing environment until the nucleating layer achieves a thickness ranging from about 30 to about 50 Angstroms.

5. The method of claim 2, wherein the conformal first conductive layer is exposed to the oxygen containing environment for about one hour.

6. The method of claim 2, wherein the oxygen containing environment has a temperature of about 20 degrees Celsius and a 50 percent relative humidity.

7. The method of claim 1, wherein the forming of the nucleating layer comprises exposing the conformal first conductive layer to an environment with oxygen levels and temperature elevated above normal fabrication process conditions.

8. The method of claim 1, wherein the conformal first conductive layer and the conformal second conductive layer are formed from a material comprising aluminum.

9. The method of claim 1 further comprising after the forming of the nucleating layer, washing the semiconductor device in a water scrub.

10. A semiconductor device comprising:
a first conductive layer disposed over a substrate;
a set of first conductive supports disposed on the first conductive layer, wherein each of the first supports comprises a circumferential pillar of conductive material;
a second conductive layer disposed over the first supports above the first conductive layer, wherein portions of the second conductive layer not overlying the first supports are separated from the first conductive layer by a vacuum or a gas;
a nucleating layer disposed over the second conductive layer; and
a third conductive layer disposed over the nucleating layer.

11. The semiconductor device of claim 10, wherein the first conductive layer, the second conductive layer, and the third conductive layer each comprise a metallic material.

12. The semiconductor device of claim 10, wherein the set of first supports are disposed on the first conductive layer in a rectangular or diamond array pattern.

13. The semiconductor device of claim 10, wherein the second layer comprises movable structures, wherein each movable structure is connected to the first conductive layer by a respective one of the first conductive supports, and wherein each movable structure pivots about an axis.

14. The semiconductor device of claim 10 further comprising:
a fourth conductive layer disposed above the substrate and beneath the first conductive layer; and
a set of second conductive supports disposed on the fourth conductive layer, wherein each of the first supports comprises a circumferential pillar of conductive material.

15. The semiconductor device of claim 14, wherein each of the second conductive supports is offset from a respective one of the first supports.

16. The semiconductor device of claim 14, wherein the first conductive layer comprises a multilayer film, the multilayer film comprising:
a fifth conductive layer disposed over the second supports above the fourth conductive layer, wherein portions of the fifth conductive layer not overlying the second supports are separated from the fourth layer by a vacuum or a gas;
a second nucleating layer disposed over the fifth conductive layer; and
a sixth conductive layer disposed over the nucleating layer.

17. The semiconductor device of claim 10, wherein the semiconductor device comprises a digital micromirror device.

18. A method for fabricating a semiconductor device, the method comprising:
forming a first conductive layer on a substrate;
depositing a first spacer layer on the first conductive layer;
creating a first opening in the first spacer layer to expose at least a portion of the first conductive layer;
forming a second conductive layer over the first spacer layer, conformally coating an interior of the first opening;
forming a nucleating layer on the second conductive layer;
forming a third conductive layer over the nucleating layer; and
removing the first spacer layer.

19. The method of claim 18, wherein the forming of the nucleating layer comprises exposing the second conductive layer to an oxygen containing environment.

20. The method of claim 18, further comprising, prior to the depositing of the first conductive layer:
forming a fourth conductive layer over the substrate;
depositing a second spacer layer over the fourth conductive layer; and
creating a second opening in the second spacer layer to expose at least a portion of the fourth conductive layer, wherein the first conductive layer is formed over the second spacer layer, conformally coating an interior of the second opening.
